(19) United States
(12) Patent Application Publication
(10) Pub. No.: US 2004/0005730 A1
(43) Pub. Date: Jan. 8, 2004

(54) Controller module for a semiconductor manufacturing device

(76) Inventor: Bu-Jin Ko, Joong-gu (KR)

Correspondence Address: BAKER & DANIELS, 300 NORTH MERIDIAN STREET, SUITE 2700, INDIANAPOLIS, IN, 46204-1782, US

(21) Appl. No.: 10/373,975

(22) Filed: Feb. 25, 2003

(30) Foreign Application Priority Data
Jul. 4, 2002 (KR) 2002-38673

(51) Int. Cl. H01L 21/44

(52) U.S. Cl. 438/100

(57) ABSTRACT

A controller module for a semiconductor manufacturing device wherein the controller module has a plurality of controllers comprises a control box disposed at an outside of the semiconductor manufacturing device wherein each of the plurality of controllers is separately installed into the control box, and a movable control box support wherein the control box is loaded on the control box support and slides on the control box support.

This application claims the benefit of Korean Patent Application No. 2002-38673, filed on Jul. 4, 2002 in Korea, which is hereby incorporated by reference for all purposes as if fully set forth herein.

### BACKGROUND OF THE INVENTION

1. Field of the Invention

The present invention relates to an apparatus for manufacturing a semiconductor device and more particularly, to a controller module of an apparatus for manufacturing a semiconductor device in which a plurality of controllers are installed into a control boxes that can slide on a movable control box support to facilitate a maintenance of the controller.

2. Discussion of the Related Art

Generally, a semiconductor manufacturing system mainly has a semiconductor manufacturing apparatus, a plurality of controllers and other auxiliary facilities. Many processes such as a photolithographic process, a development, an etching, oxidization, and a deposition are performed to a silicon wafer for the semiconductor device by the semiconductor manufacturing apparatus. The controller separately controls each semiconductor manufacturing apparatus to control a semiconductor manufacturing processes. The auxiliary facilities are to back up the semiconductor manufacturing apparatus.

FIG. 1 is a perspective view of a typical semiconductor manufacturing apparatus. In FIG. 1, the typical semiconductor manufacturing apparatus has a main chamber 10 and a plurality of controllers 21, 22 and 23. The controllers 21, 22 and 23 may be installed in several layers and respectively attached to the semiconductor manufacturing apparatus or they may be installed around the semiconductor manufacturing apparatus considering conveniences for maintenance of the semiconductor manufacturing apparatus. However, if the controllers 21, 22 and 23 are scattered around the semiconductor manufacturing apparatus, it is not efficient for an operator to move here and there to operate each of the controllers around the semiconductor manufacturing apparatus. In addition, the semiconductor manufacturing apparatus occupies a certain space for an installation and besides a further space is required for the maintenance of the controllers. Moreover, if the controllers are installed onto the semiconductor manufacturing apparatus in a layered structure, an upper controller on a lower controller must be separated away before repairing the lower controller. Accordingly, because it needs an additional work for the maintenance of the controller and a further space for the maintenance work, the space for the semiconductor manufacturing apparatus becomes large. The requirement of the large space for operating the semiconductor manufacturing apparatus is a disadvantageous factor in a semiconductor-manufacturing field where a size of the semiconductor manufacturing apparatus tends to become larger.

Therefore, a method for reducing a space that is occupied by the semiconductor manufacturing apparatus and a method for facilitating the maintenance of the controller are required.

### SUMMARY OF THE INVENTION

Accordingly, the present invention is directed to a controller module for a semiconductor manufacturing device that substantially obviates one or more of problems due to limitations and disadvantages of the related art.

An advantage of the present invention is to provide a controller module for a semiconductor manufacturing device in which a control box having a plurality of controllers is loaded on a movable control box support and slides on the movable control box support to facilitate a repair and maintenance work.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, a controller module for a semiconductor manufacturing device, wherein the controller module has a plurality of controllers, comprises a control box disposed at an outside of the semiconductor manufacturing device, wherein each of the plurality of controllers is separately installed into the control box; and a movable control box support, wherein the control box is loaded on the control box support and slides on the control box support.

The control box support includes a sliding equipment for sliding the control box on the control box support. The sliding equipment is a linear motion system and the linear motion system includes a guide rail and a movable body that can be attached to a bottom of the control box.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a perspective view of a typical semiconductor manufacturing apparatus; and

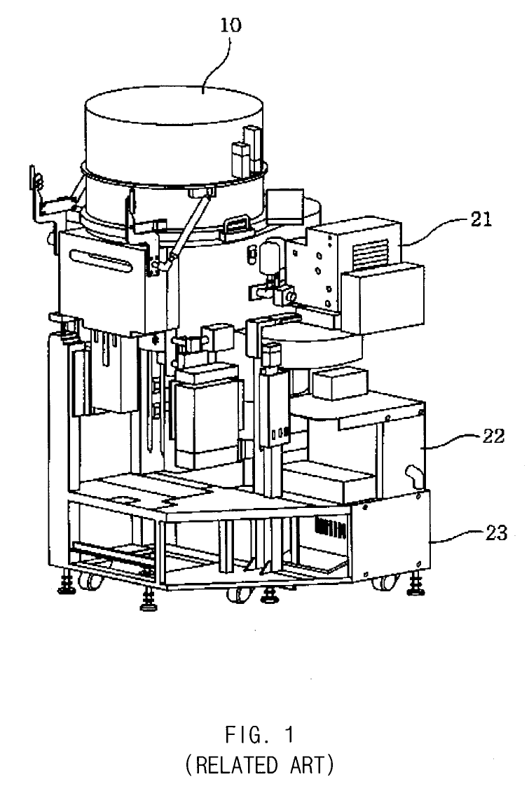

FIG. 2 is a perspective view of a controller module of a semiconductor manufacturing apparatus according to the present invention.

### DETAILED DESCRIPTION OF THE ILLUSTRATED EMBODIMENTS

Reference will now be made in detail to the illustrated embodiment of the present invention, which is illustrated in the accompanying drawings.

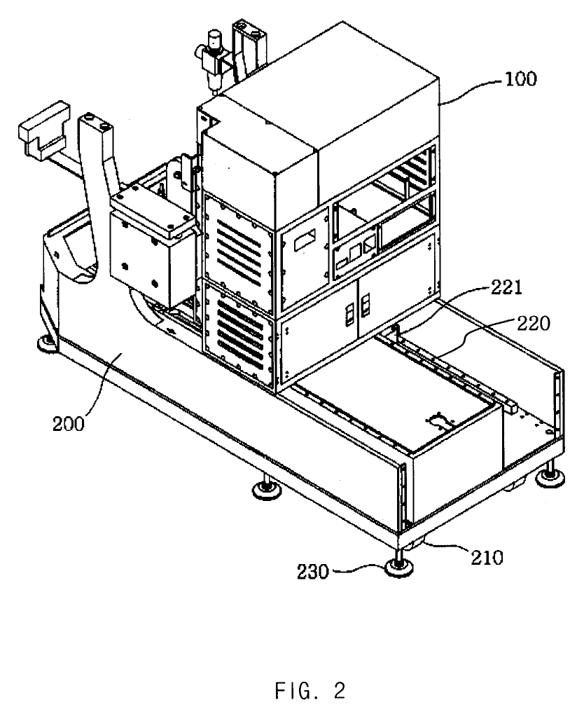

FIG. 2 is a perspective view of a controller module of a semiconductor manufacturing apparatus according to the present invention. In FIG. 2, a controller module for a semiconductor manufacturing apparatus according to the present invention has a plurality of controllers, a control box 100 and a movable control box support 200. The plurality of controllers are installed into the control box 100 and partitioned into many compartment in the control box 100. A sliding plate (not shown) is installed on a bottom of each compartment to facilitate a loading of the controller (not shown) into the compartment and a separation of the controller from the compartment. Accordingly, each controller is first put on the sliding plate and then the sliding plate slides into the control box 100 to dispose the controller in the control box 100. The controller can be separated away from the control box 100 by sliding the sliding plate out of the control box 100. Accordingly, when one of the controllers requires a repair or maintenance, the repair and maintenance work can be performed without an interference of other controllers.

The control box support 200 mainly has a plurality of rollers or wheels 210, a plurality of legs 230, sliding equipment having two pair of a guide rail 220 and a movable body 221. The plurality of wheels is installed on the bottom of the control box support 200 to move the control box support 200. The plurality of legs is also installed on the bottom of the control box support 200 to fix a position of the control box support 200. A linear motion system is used for the sliding equipment of the present invention. The control box 100 is loaded on the sliding equipment and then slides forward and backward. As stated above, the sliding equipment has two pair of the guide rail 220 and the movable body 221 that moves linearly along the guide rail 220. Each pair of the linear motion system, i.e., the guide rail 220 and the movable body 221, is installed on both sides of the control box support 200. The movable body 221 is attached to the bottom of the control box 100 and thus the control box can move forward and backward by a manual or automatic operation. Accordingly, when the controller needs the repair or maintenance work, an operator can perform the repair and maintenance work after moving the control box support 200 to a suitable place for the repair and maintenance work. Moreover, the repair and maintenance work can be easily performed to the controller by sliding the control box 100 on the control box support 200 while the control box support 200 is fixed to an originally installed place.

As stated above, the size of the semiconductor manufacturing apparatus can be reduced by installing the plurality of controllers into the movable control box 100 and the repair and maintenance work can be easily performed by moving the control box 100 to a suitable place for the required work according to the present invention. Moreover, as a size of a wafer becomes larger, the productivity and the production yield can be improved according to the present invention.

It will be apparent to those skilled in the art that various modifications and variation can be made in the fabrication and application of the present invention without departing from the spirit or scope of the invention. Thus, it is intended that the present invention cover the modifications and variations of this invention provided they come within the scope of the appended claims and their equivalents.

What is claimed is:

1. A controller module for a semiconductor manufacturing device, wherein the controller module has a plurality of controllers, comprising:
a control box disposed at an outside of the semiconductor manufacturing device,
wherein each of the plurality of controllers is separately installed into the control box; and
a movable control box support,
wherein the control box is loaded on the control box support and slides on the control box support.

2. The controller module according to claim 1, wherein the control box support includes a sliding equipment for sliding the control box on the control box support.

3. The controller module according to claim 2, wherein the sliding equipment is a linear motion system.

4. The controller module according to claim 3, wherein the linear motion system includes a guide rail and a movable body that can be attached to a bottom of the control box.
